(19) United States
(12) Patent Application Publication
(10) Pub. No.: US 2015/0368597 A1
(43) Pub. Date: Dec. 24, 2015

(54) STRIPPING SOLUTION THAT IS USED FOR REMOVAL OF TITANIUM OR A TITANIUM COMPOUND AND METHOD OF WIRING FORMATION

(71) Applicant: TOKYO OHKA KOGYO CO., LTD., Kawasaki-shi (JP)

(72) Inventors: Takahiro Eto, Kawasaki-shi (JP); Mai Sugawara, Kawasaki-shi (JP)

(21) Appl. No.: 14/746,600

(22) Filed: Jun. 22, 2015

(30) Foreign Application Priority Data
Jun. 24, 2014 (JP) 2014-129153
Feb. 5, 2015 (JP) 2015-021511

(51) Int. Cl. C11D 11/00; H01L 21/768; C11D 7/36; C11D 7/04; C11D 7/02

(52) U.S. Cl. CPC C11D 11/0047; C11D 7/04; C11D 7/02; C11D 7/36; H01L 21/76802; H01L 21/7688

(57) ABSTRACT

A stripping solution that is used for removal of titanium or a titanium compound, whereby superior stripping removal performance of the solution can be stably maintained when the solution is continuously circulated, and a method of wiring formation using the stripping solution. The stripping solution includes a basic compound, hydrogen peroxide, water, and at least one of an alkali metal silicate and a bisphosphonate compound. The titanium compound may be titanium nitride, and the stripping solution may be used for removal of a hard mask including titanium or a titanium compound.

### RELATED APPLICATIONS

This application claims priority to Japanese Patent Application No. 2014-129153, filed Jun. 24, 2014; and Japanese Patent Application No. 2015-021511, filed Feb. 5 2015, the contents of which are incorporated herein by reference.

### BACKGROUND OF THE INVENTION

1. Field of the Invention

The present invention relates to a stripping solution that is used for removal of titanium or a titanium compound and a method of wiring formation using the same.

2. Related Art

A titanium film or a titanium compound film is used in various fields. For instance, a titanium compound film such as a titanium nitride film, etc. is used for coating metal products such as cutting tools or ornaments, etc. Also, a titanium film or a titanium compound film is used in etching in semiconductor device production and the like, as described below.

Generally, in etching in semiconductor device production, etc., a resist material such as a photoresist or an electron beam resist, etc. is applied to a substrate surface to be etched and etching is performed by using a resist film on which a pattern has been formed by lithographic technique as an etching mask, and thereby a predetermined pattern is formed on the substrate to be etched.

Here, depending upon an etching rate of a substrate to be etched, a resist film sometimes does not function sufficiently as an etching mask due to a problem of etching selectivity of a resist film to a substrate to be etched. Therefore, in etching such a substrate to be etched, it is customary to provide an etching mask comprising a titanium compound film such as a titanium nitride film, etc. or a titanium film, both films of which are commonly referred to as hard masks, in order to maintain a high etching selectivity of the etching mask to the substrate to be etched.

Such a hard mask comprising a titanium compound film or a titanium film is usually removed after etching of the substrate to be etched, as is the case with ordinary resist films. Conventionally, as a solution capable of removing a titanium compound film or a titanium film, an aqueous solution for removing a hard mask comprising: hydrogen peroxide; a hydroxide source; and a corrosion inhibitor to prevent a metal conductor layer underlying the hard mask from chemically reacting with hydrogen peroxide or a hydroxide source is known (refer to Patent Document 1).

Patent Document 1: U.S. Pat. No. 8,080,475, Specification

### SUMMARY OF THE INVENTION

Incidentally, in performing stripping removal of a titanium film or a titanium compound film, the stripping solution that is used for removal of titanium or a titanium compound may sometimes be continuously circulated. In such a case, it is desirable that the stripping solution stably maintains superior stripping removal performance even over time.

According to investigations made by the present inventors, when conventional stripping solutions that are used for removal of titanium or a titanium compound were circulated in a continuous manner for a long time, it was found that the stripping performance with regard to the removal of a titanium film or a titanium compound film decreased as the composition changed.

The present invention has been made in consideration of such a conventional situation, and the present invention aims to provide a stripping solution that is used for removal of titanium or a titanium compound, whereby superior stripping removal performance of the solution can be stably maintained even over time when the solution is continuously circulated, and to provide a method of wiring formation by using this stripping solution.

The present inventors conducted intensive research to solve the problem. As a result, the inventors have found that the problem can be solved by adding at least one chelating agent selected from the group consisting of an alkali metal silicate and a bisphosphonate compound to a stripping solution that is used for removal of titanium or a titanium compound and came to complete the present invention. Specifically, the present invention provides the following.

The first aspect of the present invention is a stripping solution that is used for removal of titanium or a titanium compound, containing a basic compound, hydrogen peroxide, water, and at least one chelating agent selected from the group consisting of an alkali metal silicate and a bisphosphonate compound.

The second aspect of the present invention is a method of wiring formation comprising forming a metal wiring layer by embedding metal in an etching space formed in a dielectric layer of a semiconductor multilayered laminate using a hard mask comprising titanium or a titanium compound, wherein, after the formation of the etching space, at least the hard mask is removed using the stripping solution.

According to the present invention, it is possible to provide a stripping solution that is used for removal of titanium or a titanium compound and that is capable of maintaining a superior stripping removal performance stably even over time when the solution is continuously circulated, and a wiring formation method using this stripping solution.

### DETAILED DESCRIPTION OF THE INVENTION

Stripping Solution that is Used for Removal of Titanium or a Titanium Compound

The stripping solution according to the present invention comprises a basic compound, hydrogen peroxide, water, and at least one chelating agent selected from the group consisting of an alkali metal silicate and a bisphosphonate compound. The stripping solution according to the present invention can be used without any particular limitation for stripping titanium or a titanium compound. Particularly, the stripping solution can be used preferably as a stripping solution that is used for removal of a hard mask comprising titanium or a titanium compound in etching in semiconductor device production, etc. Examples of titanium compounds include, for instance, titanium nitride.

Hydrogen peroxide removes titanium or a titanium compound by dissolution, and the removal of titanium or a titanium compound with hydrogen peroxide is accelerated by a basic compound. Thereby, the present invention displays superior stripping performance with regard to the removal of titanium or a titanium compound. Titanium or a titanium compound which is dissolved accumulates in the stripping solution while the stripping solution according to the present invention is continuously circulated. While the titanium or titanium compound which has been dissolved has an action to accelerate the decomposition of hydrogen peroxide, it is inferred that, in the stripping solution according to the present invention, at least one chelating agent selected from the group consisting of an alkali metal silicate and a bisphosphonate compound chelates such titanium or a titanium compound and thereby, the acceleration of the decomposition of hydrogen peroxide is suppressed. As a result, it is considered that a superior stripping removal performance can be maintained stably even over time when the stripping solution according to the present invention is continuously circulated.

Below, each of the components of the stripping solution according to the present invention will be described in detail, but any commercially available products can be used as the aforementioned components unless otherwise specified.

### [Basic Compounds]

Basic compounds have an action to accelerate the removal of titanium or a titanium compound by hydrogen peroxide by maintaining the stripping solution according to the present invention basic. Basic compounds are not particularly limited, as long as the basic compounds can maintain the stripping solution according to the present invention basic. Basic compounds may be used alone or in combination of two or more.

As a basic compound, for instance, a quaternary ammonium hydroxide can be used. As a quaternary ammonium hydroxide, a compound represented by the following general formula (a1) is preferable.

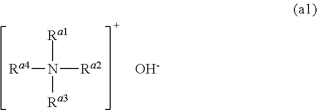

In the general formula (a1), R^{a1}-R^{a4} independently represent an alkyl group having 1 to 16 carbon atoms, an aryl group having 6 to 16 carbon atoms, an aralkyl group having 7 to 16 carbon atoms or a hydroxyalkyl group having 1 to 16 carbon atoms.

Among the compounds represented by the general formula (a1), particularly preferred is at least one selected from the group consisting of tetramethyl ammonium hydroxide, tetraethyl ammonium hydroxide, tetrapropyl ammonium hydroxide, tetrabutyl ammonium hydroxide, methyl tripropyl ammonium hydroxide, methyl tributyl ammonium hydroxide, ethyl trimethyl ammonium hydroxide, dimethyl diethyl ammonium hydroxide, benzyl trimethyl ammonium hydroxide, hexadecyl trimethyl ammonium hydroxide and (2-hydroxyethyl)trimethyl ammonium hydroxide, from the standpoint of availability. Further, from the standpoint that an action to accelerate the removal of titanium or a titanium compound by hydrogen peroxide is likely to improve, tetramethyl ammonium hydroxide and tetraethyl ammonium hydroxide are preferred.

As a basic compound, alkanolamine can be used. Examples of alkanolamines include monoethanolamine, diethanolamine, triethanolamine, 2-(2-amino ethoxy)ethanol, N,N-dimethyl ethanolamine, N,N-diethyl ethanolamine, N,N-dibutyl ethanolamine, N-methyl ethanolamine, N-ethyl ethanolamine, N-butyl ethanolamine, N-methyl diethanolamine, monoisopropanol amine, diisopropanolamine, and triisopropanolamine, etc.

As a basic compound, for instance, an inorganic base may be used. As an inorganic base, hydroxides of alkali metals such as potassium hydroxide, sodium hydroxide, and rubidium hydroxide, etc. are preferable, and potassium hydroxide is more preferable.

A basic compound preferably includes a quaternary ammonium salt, and also preferably both a quaternary ammonium salt and an inorganic base.

The content of a basic compound is preferably 0.05 to 10 mass %, more preferably 0.1 to 5 mass %, relative to the total amount of the stripping solution in the case of a quaternary ammonium hydroxide, while the content is preferably 0.05 to 20 mass %, more preferably 0.1 to 10 mass % in the case of an alkanolamine. By setting the content to these ranges, it becomes easy to maintain the stripping solution according to the present invention basic and thereby the removal of titanium or a titanium compound by hydrogen peroxide can be accelerated effectively. Incidentally, when an inorganic base is used together with a quaternary ammonium hydroxide, the content of the inorganic base is preferably 0.1 mass ppm to 1 mass %, more preferably, 1 mass ppm to 1000 mass ppm, relative to the total amount of a washing liquid for lithography. By setting the content to these ranges, it becomes easy to maintain the stripping solution according to the present invention basic and thereby the removal of titanium or a titanium compound by hydrogen peroxide can be accelerated effectively.

### [Hydrogen Peroxide]

Hydrogen peroxide dissolves titanium or a titanium compound by oxidizing titanium to a titanyl ion (TiO²⁺) as an oxidizer. The etching of titanium or a titanium compound proceeds by such an action.

The content of hydrogen peroxide is preferably 0.1 to 40 mass %, more preferably 5 to 30 mass % relative to the total amount of the stripping solution. If the content of hydrogen peroxide is 0.1 mass % or more, it is easy to maintain a high solubility of titanium or a titanium compound in the stripping solution and it is also easy to adjust the etching rate of titanium or a titanium compound to practical ranges. If the content of hydrogen peroxide is 40 mass % or less, considerable foaming in the etching step of titanium or a titanium compound is easily suppressed, which results in a stable processing.

### [Water]

In the stripping solution according to the present invention, water is used as a solvent. The content of water is preferably 40 to 98 mass %, more preferably 50 to 95 mass %, relative to the total amount of the stripping solution. If the content of water is within the aforementioned range, water can uniformly dissolve other components as a solvent particularly in a stable manner.

[At Least One Chelating Agent Selected from the Group Consisting of an Alkali Metal Silicate and a Bisphosphonate Compound]

The stripping solution according to the present invention contains at least one chelating agent selected from the group consisting of an alkali metal silicate and a bisphosphonate compound and thereby the solution can maintain a superior stripping removal performance stably even over time when the stripping solution according to the present invention is continuously circulated. Each of alkali metal silicates and bisphosphonate compounds may be used alone or in combination of two or more.

Examples of alkali metal silicates include potassium silicate and sodium silicate, etc. In preparing the stripping solution according to the present invention, an alkali metal silicate itself may be mixed with other components or a solution obtained by dissolving silica in an aqueous solution of an alkali metal hydroxide such as potassium hydroxide or sodium hydroxide, etc. may be mixed with other components.

A bisphosphonate compound is an organophosphorus compound having a structure wherein one carbon atom is held between two phosphate residues which are directly connected to this carbon atom, and has a bond represented by P-C-P. The bisphosphonate compound coordinates so that the two phosphate residues hold a metal ion therebetween, and thereby the bisphosphonate compound exhibits a chelating effect. Examples of bisphosphonate compounds include etidronic acid, alendronic acid, Mino Delon acids, risedronic acid, zoledronic acid, pamidronic acid, tiludronic acid, salts of any of these (e.g., a salt of etidronic acid with tetramethyl ammonium hydroxide) and the like. Among bisphosphonate compounds, etidronic acid is particularly preferable because it is easily available and easy to use.

The content of an alkali metal silicate is preferably 1 mass ppm to 10 mass %, more preferably 10 mass ppm to 5 mass %, in terms of SiO₂, relative to the total amount of the stripping solution. Further, the content of a bisphosphonate compound is preferably 0.01 to 10 mass %, more preferably 0.1 to 5 mass %, relative to the total amount of the stripping solution. When the contents of an alkali metal silicate and/or a bisphosphonate compound are within the above-described ranges, the stripping solution according to the present invention can maintain a superior stripping removal performance particularly stably even over time when the stripping solution according to the present invention is continuously circulated.

### [Other Components]

To the stripping solution according to the present invention, other components, such as an anticorrosive, a surfactant, or a water-soluble organic solvent, etc. may be added. Anticorrosives are not particularly limited and examples thereof include for instance, imidazole-based compounds, triazole-based compounds, and mercapto group-containing compounds, etc. Surfactants are not particularly limited and examples thereof include nonionic-based surfactants, anion-based surfactants, cation-based surfactants, and amphoteric surfactants, etc. Water-soluble organic solvents are not particularly limited and those which are resistant to hydrogen peroxide, which is an oxidant, and which have a high solubility in water are preferably used. Examples of water-soluble organic solvents include, for example, tertiary monovalent alcohol such as tert-butyl alcohol, etc.; tertiary polyvalent alcohol such as 2,5-dimethyl-2,5-hexanediol, etc. and dialkyl glycol ether-based solvents and so on, such as ethylene glycol dimethyl ether, diethylene glycol dimethylether, triethylene glycol dimethyl ether, tetraethylene glycol dimethyl ether, diethylene glycol methyl ethyl ether, diethylene glycol diethyl ether, etc. and, in terms of resistance to hydrogen peroxide and solubility in water, tert-butyl alcohol, diethylene glycol diethyl ether and 2,5-dimethyl-2,5-hexanediol are preferred.

### Wiring Formation Method

The wiring formation method according to the present invention is a wiring formation method using a damascene method, the wiring formation method comprising forming a metal wiring layer by embedding metal in an etching space formed in a dielectric layer of a semiconductor multilayered laminate using a hard mask comprising titanium or a titanium compound, wherein, after the formation of the etching space, at least the hard mask is removed by using the stripping solution according to the present invention.

More specifically, in the wiring formation method using a damascene method, a metal wiring is formed by etching a low dielectric layer, using a hard mask formed on the low dielectric layer of a semiconductor multilayered laminate as a mask to form an etching space, and embedding metal in this etching space. Incidentally, another sacrificial film may be sometimes embedded in the etching space temporarily.

The method of removing a hard mask is not particularly limited, as long as the removing method is generally used. Specifically, a hard mask is processed by bringing a substrate into contact with the stripping solution according to the present invention for 1 to 40 minutes, using a dipping method, a paddle method, a shower method, etc. In order to enhance a removal effect, the removal processing may be performed by heating the stripping solution to about 85° C., though the stripping solution is usually at room temperature.

Specifically, the dielectric layer is a layer formed by, for instance, carbon doped oxide (SiOC) based material, methyl silsesquioxane (MSQ) based material, or hydrogen silsesquioxane (HSQ) based material. In order to avoid affecting the electrical characteristics of the metal wiring layer, dielectric constant (k) is preferably 3.0 or less, more preferably 2.5 or less. The dielectric layer may be formed on the metal wiring layer or on a barrier layer formed on the metal wiring layer. The calcination temperature of the dielectric layer is usually higher than 350° C. or more.

A metal material to form a metal wiring layer used in the damascene method is principally Cu, but electrically conductive materials other than Cu such as Al, Ti, W, etc. may also be laminated on the same substrate.

### EXAMPLES

Below, the Examples of the present invention will be shown to describe the present invention further in detail, but the present invention is not limited to the following examples.

### (Preparation of the Stripping Solution)

The materials represented in Table 1 or 2 were mixed in the amounts represented in Table 1 or 2 to prepare the stripping solutions (“%” represents mass % and “ppm” represents mass ppm). In Tables 1 and 2, TMAH refers to tetramethyl ammonium hydroxide and in Table 2, EDTA refers to ethylenediaminetetraacetic acid. In Example 3, a solution obtained by dissolving SiO₂ in an aqueous NaOH solution was used as an alkali metal silicate (SiO₂ concentration: 12.2 mass %, NaOH concentration: 16.0 mass %). In Example 4, a solution obtained by dissolving SiO₂ in an aqueous KOH solution was used as an alkali metal silicate (SiO₂ concentration: 10.0 mass %, KOH concentration: 18.7 mass %). Incidentally, as each of the reagents, commercially available ones were used, unless otherwise specified. The quantities of the alkali metal silicates in Table 1 are given in terms of SiO₂.

### (Evaluation of Stability Over Time of Etching Rate)

Titanium nitride was formed into a film on a silicon wafer to obtain a silicon wafer comprising a titanium nitride film having a thickness of 100 nm. The sheet resistance value of this titanium nitride film was measured using a sheet resistance measuring instrument (VR-70S, manufactured by Kokusai Electric Inc.) to obtain a conversion formula of film thicknesses and sheet resistance values.

The freshly prepared stripping solution was warmed to 55° C. and the silicon wafer was immersed in the warmed stripping solution for one minute. After the completion of immersion, the silicon wafer was rinsed with pure water, the sheet resistance value of the titanium nitride film was measured, and the film thickness of the titanium nitride film was calculated using the conversion formula. The etching rate was obtained from a difference in the film thicknesses before and after the immersion. The results are shown in Tables 1 and 2.

The following experiments were performed in order to obtain in a simulated manner the etching rate of the stripping solution which had been continuously circulated. Particulate titanium nitride was added to a freshly prepared stripping solution and was dissolved (final concentration: 0.01 mass %) and the stripping solution after the titanium nitride dissolved was left to stand at 50° C. for 24 hours. Using the stripping solution after the standing, the etching rate of the titanium nitride film was measured in the same manner as the above. The results are shown in Tables 1 and 2.

TABLE 1

| | | | | Alkali metal | | | | | | |
|---|---|---|---|---|---|---|---|---|---|---|
| | Basic | | | silicate or | | Anticorrosive | | | Etching rate | |
| | compound | | Hydrogen | bisphosphonate | | 1,2,4- | Water-soluble | | (Å/min.) | |
| | TMAH | KOH | peroxide | compound | Stabilizer | Triazole | organic solvent | Water | Initial | Over time |
| Example 1 | 0.80% | 400 ppm | 10% | K₂Si0₃ | — | 0.47% | — | Balance | 131 | 128 |
| | | | | 840 ppm* | | | | | | |
| Example 2 | 0.80% | 400 ppm | 10% | Na₂Si0₃ | — | 0.47% | — | Balance | 129 | 125 |
| | | | | 840 ppm* | | | | | | |
| Example 3 | 0.80% | 400 ppm | 10% | SiO₂ solution | — | 0.47% | — | Balance | 132 | 127 |
| | | | | (dissolved in | | | | | | |
| | | | | an aqueous | | | | | | |
| | | | | NaOH solution) | | | | | | |
| | | | | 300 ppm* | | | | | | |
| Example 4 | 0.80% | 400 ppm | 10% | SiO₂ solution | — | 0.47% | — | Balance | 128 | 124 |
| | | | | (dissolved in | | | | | | |
| | | | | an aqueous | | | | | | |
| | | | | KOH solution) | | | | | | |
| | | | | 300 ppm* | | | | | | |
| Example 5 | 1.7% | 700 ppm | 10% | Etidronic acid | — | 0.47% | — | Balance | 130 | 128 |
| | | | | 0.20% | | | | | | |
| Example 6 | 1.7% | 700 ppm | 10% | Etidronic acid | — | 0.47% | — | Balance | 135 | 130 |
| | | | | 0.50% | | | | | | |
| Example 7 | 1.7% | 700 ppm | 10% | Etidronic acid | — | 0.47% | — | Balance | 136 | 132 |
| | | | | 1.0% | | | | | | |
| Example 8 | 0.80% | 700 ppm | 10% | Salt of | — | 0.47% | — | Balance | 132 | 128 |
| | | | | etidronic acid | | | | | | |
| | | | | with TMAH | | | | | | |
| | | | | 0.80% | | | | | | |
| Example 9 | 1.7% | 700 ppm | 10% | Etidronic acid | — | 0.47% | tert-Butyl | Balance | 150 | 141 |
| | | | | 0.20% | | | alcohol | | | |
| | | | | | | | 7% | | | |
| Example 10 | 1.7% | 700 ppm | 10% | Etidronic acid | — | 0.47% | Diethylene | Balance | 153 | 140 |
| | | | | 0.20% | | | glycol | | | |
| | | | | | | | diethyl ether | | | |
| | | | | | | | 7% | | | |
| Example 11 | 1.7% | 700 ppm | 10% | Etidronic acid | — | 0.47% | 2,5-Dimethyl- | Balance | 149 | 139 |
| | | | | 0.20% | | | 2,5-hexanediol | | | |
| | | | | | | | 7% | | | |

*In terms of SiO₂

TABLE 2

| | | | | Alkali metal | | | | | | |
|---|---|---|---|---|---|---|---|---|---|---|
| | Basic | | | silicate or | | Anticorrosive | | | Etching rate | |
| | compound | | Hydrogen | bisphosphonate | | 1,2,4- | Water-soluble | | (Å/min.) | |
| | TMAH | KOH | peroxide | compound | Stabilizer | Triazole | organic solvent | Water | Initial | Over time |
| Comparative | 0.80% | 400 ppm | 10% | — | EDTA | 0.47% | — | Balance | 125 | 43 |
| Example 1 | | | | | 0.10% | | | | | |
| Comparative | 0.80% | 400 ppm | 10% | — | EDTA | 0.47% | — | Balance | 129 | 49 |
| Example 2 | | | | | 0.50% | | | | | |
| Comparative | 0.80% | 400 ppm | 10% | — | Phenanthroline | 0.47% | — | Balance | 134 | 18 |
| Example 3 | | | | | 0.10% | | | | | |
| Comparative | 0.80% | 400 ppm | 10% | — | Phenanthroline | 0.47% | — | Balance | 126 | 19 |
| Example 4 | | | | | 0.50% | | | | | |
| Comparative | 0.80% | 400 ppm | 10% | — | Sulfuric acid | 0.47% | — | Balance | 122 | 16 |
| Example 5 | | | | | 0.50% | | | | | |
| Comparative | 0.80% | 400 ppm | 10% | — | Sulfuric acid | 0.47% | — | Balance | 115 | 14 |
| Example 6 | | | | | 1.0% | | | | | |

As can be seen from Table 1, it was confirmed that the stripping solutions of Examples 1 to 11 each containing an alkali metal silicate or a bisphosphonate compound were superior not only in an initial stripping removal performance, but also in maintaining the superior stripping removal performance stably over time.

On the other hand, as can be seen from Table 2, the etching rate of the stripping solutions of Comparative Examples 1-6 each containing conventional stabilizers such as EDTA, phenanthroline, or sulfuric acid, etc. instead of an alkali metal silicate or a bisphosphonate compound decreased greatly over time and it was confirmed that a superior stripping removal performance could not be maintained stably over time.

What is claimed is:

1. A stripping solution comprising a basic compound, hydrogen peroxide, water, and at least one chelating agent selected from the group consisting of an alkali metal silicate and a bisphosphonate compound.

2. A method of wiring formation, comprising forming a metal wiring layer by embedding metal in an etching space formed in a dielectric layer of a semiconductor multilayered laminate using a hard mask comprising titanium or a titanium compound,
wherein, after the formation of the etching space, the hard mask is removed using the stripping solution according to claim 1.

3. A method of removing titanium or a titanium compound, comprising using the stripping solution according to claim 1.

4. The method according to claim 3, wherein the titanium compound is titanium nitride.

5. The method according to claim 3, wherein the titanium or the titanium compound is comprised in a hard mask.
